(19) United States
(12) Patent Application Publication
(10) Pub. No.: US 2022/0376145 A1
(43) Pub. Date: Nov. 24, 2022

(54) MICRO LIGHT-EMITTING DIODE CHIP AND MANUFACTURING METHOD THEREFOR, AND DISPLAY DEVICE

(71) Applicant: CHONGQING KONKA PHOTOELECTRIC TECHNOLOGY RESEARCH INSTITUTE CO., LTD., Chongqing (CN)

(72) Inventors: Shun-Kuei YANG, Chongqing (CN); Chia-Hung HUANG, Chongqing (CN); Ya-Wen LIN, Chongqing (CN); Mao-Chia HUNG, Chongqing (CN)

(21) Appl. No.: 17/287,120

(22) PCT Filed: Dec. 31, 2019
(86) PCT No.: PCT/CN2019/130724

§ 371 Date: Apr. 21, 2021

(51) Int. Cl. H01L 33/46; H01L 25/075; H01L 33/32; H01L 33/38; H01L 33/00

(52) U.S. Cl. CPC H01L 33/46; H01L 25/0753; H01L 33/32; H01L 33/382; H01L 33/0075; H01L 2933/0025

(57) ABSTRACT

Provided are a micro light-emitting diode chip and a manufacturing method therefor, and a display device. The micro light-emitting diode chip comprises: a first-type semiconductor layer, a light-emitting layer and a second-type semiconductor layer which are sequentially stacked, wherein the light-emitting layer is located between the first-type semiconductor layer and the second-type semiconductor layer; and a reflective layer provided at a light-emitting side of the light-emitting layer, wherein the reflective layer is configured to block light emitted by the light-emitting layer to an edge of the micro light-emitting diode chip.

### TECHNICAL FIELD

The present disclosure relates to the technical field of micro light-emitting diodes, in particular to a micro light-emitting diode chip and a manufacturing method therefor, and a display device.

### BACKGROUND

A general light-emitting diode (LED) chip comprises a substrate and an epitaxy layer, and has a thickness of about 100-500 μm and a size of 100-1000 μm. The on-going study of micro light-emitting diode display (Micro LED) seeks to lift off, from the surface of a Micro LED chip, an epitaxy layer having a thickness of about 4-5 μm by using a physical or chemical mechanism, and then transfer the epitaxy layer onto a circuit board. In the study of the Micro LED, the characteristics of two techniques, i.e. a thin film transistor liquid crystal display (TFT-LCD) and an LED are integrated, so that the Micro LED has the advantages of low power consumption, high brightness, ultra-high resolution and color saturation, fast response speed, ultra-low power, long service life, and high efficiency. In addition, the power consumption of the Micro LED is about 10% of the TFT-LCD and 50% of an organic light-emitting diode (OED), and thus the Micro LED is more power-saving. The Micro LED further has the characteristic of self-luminescence without a backlight source. The development of materials, processes and devices of the Micro LED is mature, and the product specifications thereof are far higher than that of the current TFT-LCD or OLED. The Micro LED has a broader application field comprising a flexible and transparent display, and is a next-generation flat-panel display technique with high feasibility.

Currently, manufacturing the Micro LED requires an epitaxial wafer formed by an epitaxy. After a size required by the Micro LED chip is defined based on a photoresist (PR), positive and negative electrodes are formed on each chip, and finally independent chips are formed by cutting. As shown in FIGS. 1 and 2, the type of light emitted by a micro light-emitting diode chip 100 formed by cutting a micro light-emitting diode chip in the related art 100 is lambertian. Therefore, when the micro light-emitting diode chip 100 is welded onto a display panel 200, the light emitted by two adjacent micro light-emitting diode chips 100 may interfere with each other due to a lambertian phenomenon to generate a light cross. The smaller the distance between the two adjacent micro light-emitting diode chips 100 on a small-sized panel, the more serious the light cross phenomenon is. Generally, in order to solve the problem of the light cross phenomenon of the micro light-emitting diode chip 100 in the related art, the distance between the two adjacent micro light-emitting diode chips 100 is increased to reduce the light cross phenomenon. However, the resolution of the display panel 200 is deteriorated by this method. In addition, in the conventional technology, a layer of light-absorbing black glue is coated between the two adjacent micro light-emitting diode chips 100 to absorb the light sources on both sides. Although this method has an effect of reducing the light cross phenomenon, if the two adjacent micro light-emitting diode chips 100 are close to each other, the light-absorbing black glue is not filled in the gap easily and is adhered to the surface of the micro light-emitting diode chip 100 easily, causing the light intensity to decrease.

Therefore, it is very important to make improvement and development on the related art.

### SUMMARY

In view of the described deficiencies in the related art, an object of the embodiments of the present disclosure is to provide a micro light-emitting diode chip and a manufacturing method therefor, and a display device, so as to solve the problem when the micro light-emitting diode chips are welded onto a display panel that a light cross phenomenon is generated because light emitted by two adjacent micro light-emitting diode chips may interfere with each other due to a lambertian phenomenon.

The technical solution of the embodiments of the present disclosure is as follows.

A micro light-emitting diode chip comprises:

a first-type semiconductor layer, a light-emitting layer and a second-type semiconductor layer which are sequentially stacked, wherein the light-emitting layer is located between the first-type semiconductor layer and the second-type semiconductor layer; and

a reflective layer provided at a light-emitting side of the light-emitting layer, wherein the reflective layer is configured to block light emitted by the light-emitting layer to an edge of the micro light-emitting diode chip.

In an exemplary embodiment of the present disclosure, the reflective layer is embedded at an edge position of the first-type semiconductor layer.

In an exemplary embodiment of the present disclosure, the reflective layer is an oxide layer or an oxynitride layer.

In an exemplary embodiment of the present disclosure, the reflective layer is of a distributed Bragg reflector structure.

In an exemplary embodiment of the present disclosure, the first-type semiconductor layer is an N-type semiconductor layer, the second-type semiconductor layer is a P-type semiconductor layer, and the reflective layer is provided in the N-type semiconductor layer; or the first-type semiconductor layer is a P-type semiconductor layer, the second-type semiconductor layer is an N-type semiconductor layer, and the reflective layer is provided in the P-type semiconductor layer.

In an exemplary embodiment of the present disclosure, the micro light-emitting diode chip further comprises a substrate, the first-type semiconductor layer is provided on the substrate, and the reflective layer is located between the substrate and the light-emitting layer.

In an exemplary embodiment of the present disclosure, the micro light-emitting diode chip further comprises a low temperature-Gallium nitride (LT-GaN) low-temperature epitaxy layer and an undoped Gallium nitride (GaN) layer, wherein the LT-GaN low-temperature epitaxy layer is provided on the substrate, and the undoped GaN layer is provided on the LT-GaN low-temperature epitaxy layer.

In an exemplary embodiment of the present disclosure, the micro light-emitting diode chip further comprises an N electrode and a P electrode, wherein the N electrode is provided on the N-type semiconductor layer, and the P electrode is provided on the P-type semiconductor layer.

A method for manufacturing the micro light-emitting diode chip comprises:

growing a first-type semiconductor layer on a substrate;

forming a groove on the first-type semiconductor layer by using a method of photolithography and etching processes;

isolating the groove by using a photoresist at a bottom of the groove of the first-type semiconductor layer, wherein the photoresist is spaced from a sidewall of the groove;

growing, on the first-type semiconductor layer, a reflective layer having a high-reflectivity structure;

removing the photoresist;

continuing to grow the first-type semiconductor layer in the groove and on the reflective layer, so as to wrap the reflective layer in the first-type semiconductor layer; and

sequentially growing, on the first-type semiconductor layer, a light-emitting layer and a second-type semiconductor layer.

In an exemplary embodiment of the present disclosure, before growing the first-type semiconductor layer on the substrate, the method further comprises:

sequentially growing, on the substrate, an LT-GaN low-temperature epitaxy layer and an undoped GaN layer; and

growing the first-type semiconductor layer on the substrate comprises:

growing the first-type semiconductor layer on the undoped GaN layer.

In an exemplary embodiment of the present disclosure, after sequentially growing, on the first-type semiconductor layer, the light-emitting layer and the second-type semiconductor layer, the method further comprises:

evaporating a first electrode on the first-type semiconductor layer, and evaporating a second electrode on the second-type semiconductor layer.

In an exemplary embodiment of the present disclosure, the first-type semiconductor layer is an N-type semiconductor layer, the second-type semiconductor layer is a P-type semiconductor layer, and the reflective layer is grown on the N-type semiconductor layer; the first electrode is an N electrode, the second electrode is a P electrode, the N electrode is evaporated on the N-type semiconductor layer, and the P electrode is evaporated on the P-type semiconductor layer.

In an exemplary embodiment of the present disclosure, the first-type semiconductor layer is a P-type semiconductor layer, the second-type semiconductor layer is an N-type semiconductor layer, and the reflective layer is grown on the P-type semiconductor layer; the first electrode is a P electrode, the second electrode is an N electrode, the P electrode is evaporated on the P-type semiconductor layer, and the N electrode is evaporated on the N-type semiconductor layer.

In an exemplary embodiment of the present disclosure, the reflective layer is an oxide layer or an oxynitride layer.

In an exemplary embodiment of the present disclosure, the reflective layer is of a distributed Bragg reflector structure.

A display device comprises a display panel and a plurality of micro light-emitting diode chips, wherein the plurality of micro light-emitting diode chips are provided on the display panel in an array and at intervals.

The embodiments of the present disclosure provide a micro light-emitting diode chip and a manufacturing method therefor, and a display device. The micro light-emitting diode chip comprises a first-type semiconductor layer, a light-emitting layer and a second-type semiconductor layer which are sequentially stacked, wherein the light-emitting layer is located between the first-type semiconductor layer and the second-type semiconductor layer; and further comprises a reflective layer provided at a light-emitting side of the light-emitting layer, wherein the reflective layer is configured to block light emitted by the light-emitting layer to an edge of the micro light-emitting diode chip. In the embodiments of the present disclosure, the reflective layer having a high-reflectivity structure is provided on the first-type semiconductor layer, so that light emitted by the light-emitting layer to the edge of the micro light-emitting diode chip can be blocked, so as to reduce light divergence. As such, a distance between two adjacent micro light-emitting diode chips can be smaller, and a light cross phenomenon does not occur, thereby improving the resolution of a display.

### BRIEF DESCRIPTION OF THE DRAWINGS

To describe the technical solutions in the embodiments of the present disclosure or in the related art more clearly, the following briefly describes the accompanying drawings required for describing the embodiments or the related art. Apparently, the accompanying drawings in the following description show merely some embodiments of the present disclosure, and a person having ordinary skill in the art may still derive other drawings from these accompanying drawings without creative efforts.

FIG. 1 is a schematic diagram showing the type of light from a micro light-emitting diode chip in the related art.

FIG. 2 is a schematic diagram showing the type of light from a micro light-emitting diode chip in the related art on a display panel.

FIG. 3 is a structural schematic diagram of welding a micro light-emitting diode chip onto a display panel according to one or more embodiments of the present disclosure.

FIG. 4 is a structural schematic diagram of embedding a reflective layer into a first-type semiconductor layer according to one or more embodiments of the present disclosure.

FIG. 5 is a schematic diagram showing the distribution of light from a micro light-emitting diode chip.

FIG. 6 is a structural schematic diagram of manufacturing an electrode at a micro light-emitting diode chip according to one or more embodiments of the present disclosure.

FIG. 7 is a structural schematic diagram of an epitaxial wafer of a micro light-emitting diode chip according to one or more embodiments of the present disclosure.

FIG. 8 is a structural schematic diagram of a groove of a micro light-emitting diode chip on the first-type semiconductor layer according to one or more embodiments of the present disclosure.

FIG. 9 is a schematic diagram of isolating the groove of the micro light-emitting diode chip on the first-type semiconductor layer according to one or more embodiments of the present disclosure.

FIG. 10 is a structural schematic diagram of growing a reflective layer on the first-type semiconductor layer of the micro light-emitting diode chip according to one or more embodiments of the present disclosure.

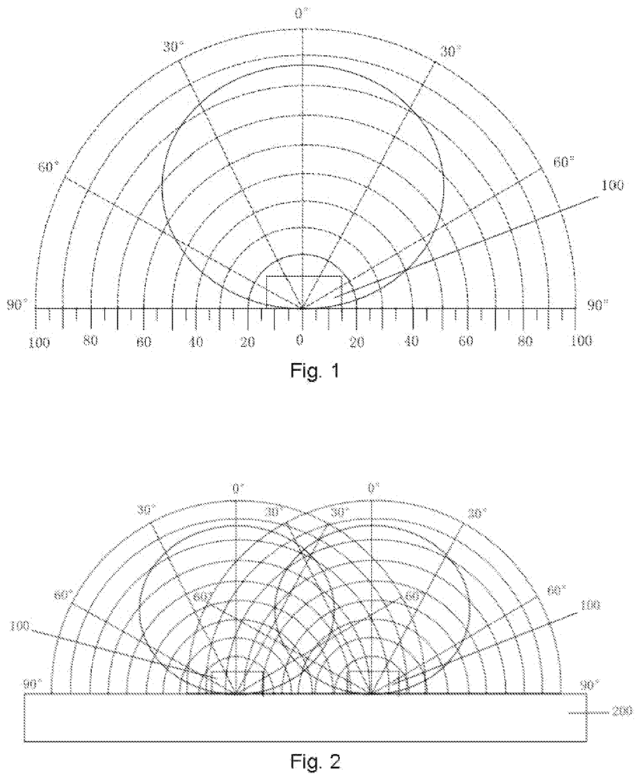

The drawings include the following reference signs: 100, micro light-emitting diode chip; 101, sapphire substrate; 102, LT-GaN low-temperature epitaxy layer; 103, undoped GaN layer; 104, first-type semiconductor layer; 105, second-type semiconductor layer; 106, light-emitting layer; 107, reflective layer; 108, first electrode; 109, second electrode; 110, photoresist; and 200, display panel.

### DETAILED DESCRIPTION OF THE EMBODIMENTS

Since the type of light emitted by a chip obtained by cutting a micro light-emitting diode chip in the related art is divergent light, when the chip is welded on the display panel, a light cross phenomenon is generated as light emitted by two adjacent micro light-emitting diode chips may interfere with each other. The embodiments of the present disclosure provide a micro light-emitting diode chip and a manufacturing method therefor, and a display device, so as to solve the problem of a light cross phenomenon generated by two adjacent micro light-emitting diode chips. Since the distance between two adjacent micro light-emitting diode chips on a small-sized panel is small, the technical scheme in the embodiments of the present disclosure is particularly applicable to a display having a small-sized panel. To make the objective, technical solutions, and technical effects of the present disclosure clearer and more definite, the following describes the present disclosure in detail with reference to drawings and embodiments. It should be understood that the embodiments described herein are only for explaining the present disclosure, but not for limiting the present disclosure.

Within the patent scope of the embodiments and the application, unless there are specific limitations to the articles in the text, the terms “a” and “the” may generally mean a single or a plurality.

In addition, if there are descriptions related to “first” and “second” in the embodiments of the present disclosure, the descriptions of “first” and “second” are only used for the purpose of describing, and cannot be understood as indication or implication of relative importance or implicit indication of the number of specified technical features. Therefore, the technical features limited by the term “first” or “second” may explicitly or implicitly include at least one of the features. In addition, the technical solutions of the embodiments can be combined with each other as long as the technical solution can be implemented by a person having ordinary skill in the art. When the combination of the technical solutions is contradictory or cannot be implemented, it should be considered that the combination of the technical solutions does not exist, and is not within the scope of protection of the present disclosure.

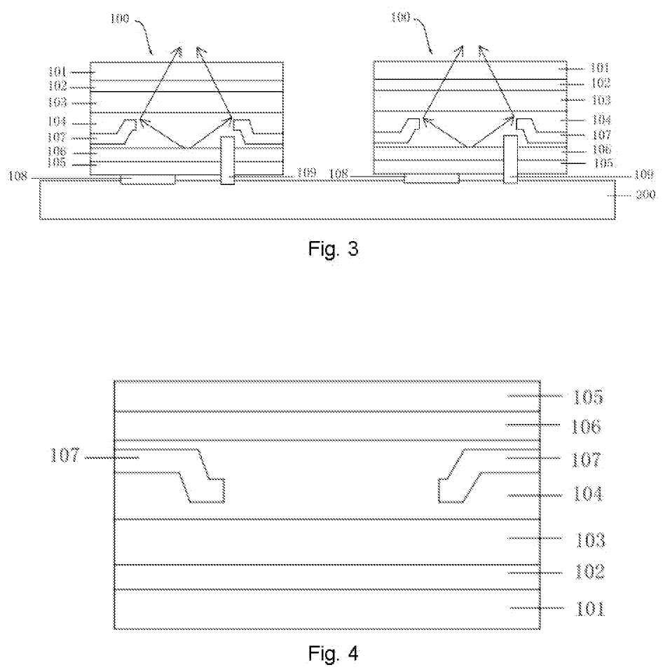

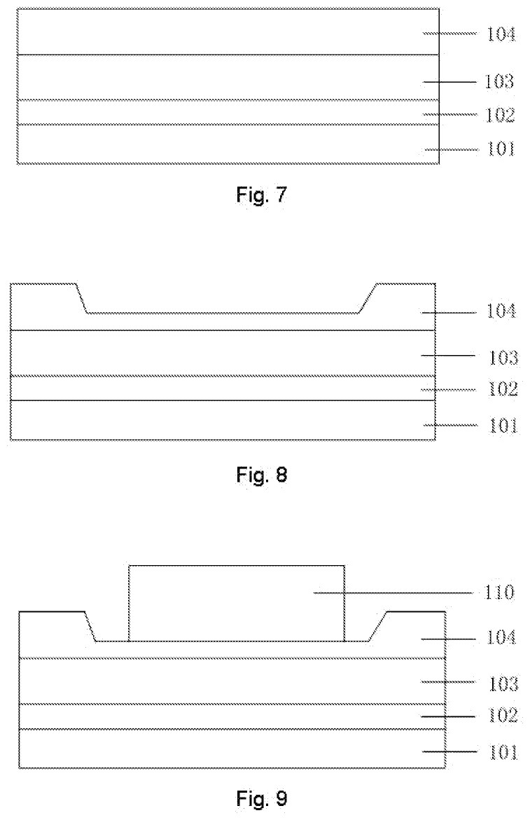

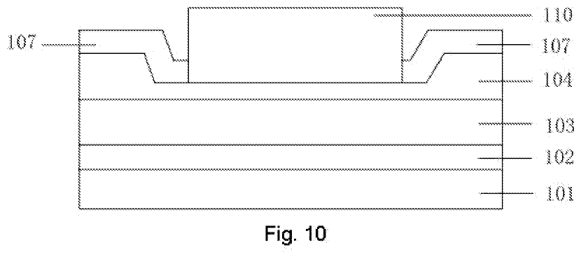

Referring to FIGS. 3 to 10, the present disclosure provides an exemplary embodiment of a micro light-emitting diode chip.

Referring to FIG. 3, the micro light-emitting diode chip applied to a display panel 200 comprises a substrate, a first-type semiconductor layer 104, a second-type semiconductor layer 105, a light-emitting layer 106 and a reflective layer 107. Specifically, the substrate may be a sapphire substrate 101. An LT-GaN low-temperature epitaxy layer 102 and an undoped GaN layer 103 are further grown on the sapphire substrate 101. Growing the LT-GaN low-temperature epitaxy layer 102 on the sapphire substrate 101, i.e. forming a seed crystal layer on the sapphire substrate 101 is beneficial to subsequent growing of a high-quality epitaxy layer. Growing the undoped GaN layer 103 on the LT-GaN low-temperature epitaxy layer 102, i.e. growing the high-quality epitaxy layer on the sapphire substrate 101 is beneficial to subsequent growing of a high-quality LED epitaxy layer structure. The first-type semiconductor layer 104 is provided on the undoped GaN layer 103, the light-emitting layer 106 is provided in the first-type semiconductor layer 104, and the second-type semiconductor layer 105 is provided in the light-emitting layer 106, i.e. the light-emitting layer 106 is located between the first-type semiconductor layer 104 and the second-type semiconductor layer 105. The reflective layer 107 is provided between the sapphire substrate 101 and the light-emitting layer 106, wherein the reflective layer 107 may be provided in the first-type semiconductor layer 104, and may alternatively be provided on other semiconductor layers at the light-emitting side of the light-emitting layer 106, such as the LT-GaN low-temperature epitaxy layer 102 and the undoped GaN layer 103.

As compared with the related art, in the embodiments of the present disclosure, there is no need to increase the distance between two adjacent micro light-emitting diode chips 100, and coat a light-absorbing black glue between the two adjacent micro light-emitting diode chips 100. In the embodiments of the present disclosure, the reflective layer 107 having a high-reflectivity structure is provided between the sapphire substrate 101 and the light-emitting layer 106, so that light emitted by the light-emitting layer to the edge of the micro light-emitting diode chip can be blocked, so as to reduce light divergence, and thus the light reflected by the light-emitting layer 106 is not divergent, changing the type of light from a divergent type to a torch type. Therefore, the distance between two the adjacent micro light-emitting diode chips 100 can be smaller, and a light cross phenomenon does not occur, thereby improving the resolution of the display panel 200. It should be noted that the micro light-emitting diode chip 100 may be square, circular, etc., and the actual shape of the micro light-emitting diode chip 100 can be set according to actual requirements. The embodiment of the present disclosure does not limit the shape of the micro light-emitting diode chip 100.

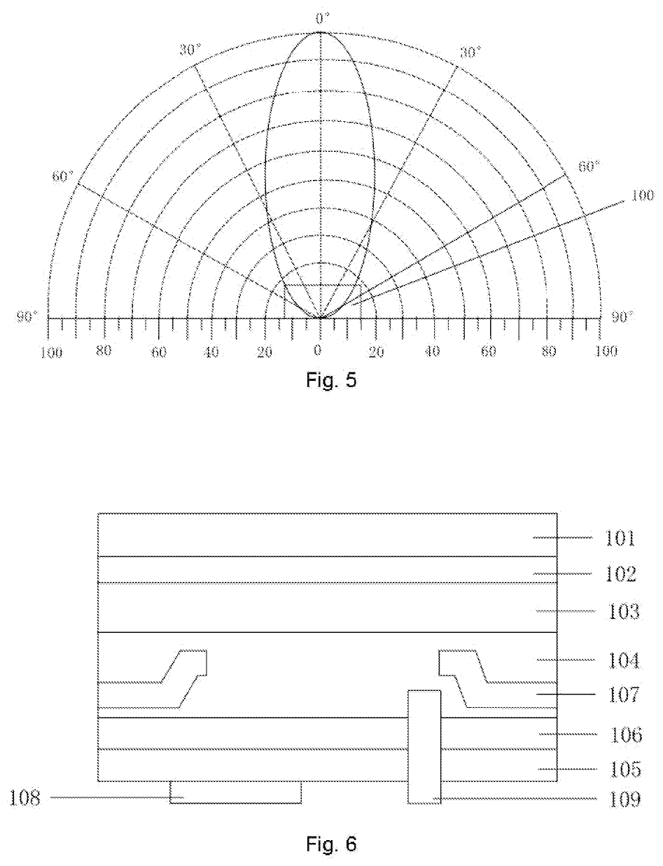

Referring to FIGS. 4 and 5, in an exemplary implementation of an embodiment, the reflective layer 107 is embedded at an edge position of the first-type semiconductor layer 104. Specifically, the reflective layer 107 is embedded at the edge position, close to the substrate, of the first-type semiconductor layer 104. When the light emitted by the light-emitting layer 106 is diverged toward the first-type semiconductor layer 104, the reflective layer 107 has a blocking effect on the light emitted by the light-emitting layer 106, and can reflect, in an upwardly tilted direction, the light emitted by the light-emitting layer 106, so that the original type of light is changed from a divergent type into a torch type, that is, the light divergence can be reduced.

The reflective layer 107 is an oxide layer or an oxynitride layer, such as SiOx, SiNx, Ta2O5 and NOx. In addition, the reflective layer 107 is of a distributed Bragg reflector (DBR) structure, wherein the DBR structure is a repetitive stack structure having two materials of different refractive indexes, and has a characteristic of a high reflectivity at a specific wavelength. The operating principle of the DBR structure is that: fresnel reflection occurs at each interface of the two materials, and at a operating wavelength, the optical path difference of the reflected light at two adjacent interfaces is a half wavelength, and in addition, the signs of reflection coefficients at the interfaces also change. Therefore, all the reflected light at the interfaces destructively interferes, so as to obtain a strong reflection, wherein the reflectivity depends on the number of layers of materials and the refractive index difference between the materials, and the reflection bandwidth mainly depends on the refractive index difference.

In an exemplary implementation of the embodiment, the first-type semiconductor layer 104 is an N-type semiconductor layer, the second-type semiconductor layer 105 is a P-type semiconductor layer, and the reflective layer 107 is provided in the N-type semiconductor layer. Specifically, the light-emitting layer 106 is provided between the first-type semiconductor layer 104 and the second-type semiconductor layer 105, i.e., the light-emitting layer 106 is provided between the N-type semiconductor layer and the P-type semiconductor layer, and the light-emitting direction of the light-emitting layer 106 is also towards the N-type semiconductor layer. Accordingly, the reflective layer 107 needs to be provided in the N-type semiconductor layer, so as to prevent divergence of the light emitted by the light-emitting layer 106, and a light source generated by the light-emitting layer 106 is enabled to pass through a non-evaporated N-type semiconductor according to different element structures, so as to generate a torch light-field.

Referring to FIG. 6, in an exemplary implementation of the embodiment, the micro light-emitting diode chip 100 further comprises an N electrode 108 and a P electrode 109, wherein the N electrode 108 is provided on the N-type semiconductor layer, and the P electrode 109 is provided on the P-type semiconductor layer.

In another exemplary implementation of the embodiment, the first-type semiconductor layer 104 is a P-type semiconductor layer, the second-type semiconductor layer 105 is an N-type semiconductor layer, and the reflective layer 107 is provided in the P-type semiconductor layer. The light-emitting layer 106 is provided between the first-type semiconductor layer 104 and the second-type semiconductor layer 105, i.e., the light-emitting layer 106 is provided between the P-type semiconductor layer and the N-type semiconductor layer, and the light-emitting direction of the light-emitting layer 106 is also towards the P-type semiconductor layer. Accordingly, the reflective layer 107 needs to be provided in the P-type semiconductor layer, so as to prevent divergency of the light emitted by the light-emitting layer 106, and enable a light source generated by the light-emitting layer 106 to pass through a non-evaporated P-type semiconductor according to different element structures, so as to generate a torch-light field.

Referring to FIGS. 4 to 10, an embodiment of the present disclosure provides a method for manufacturing a micro light-emitting diode chip. The method comprises operations 1 to 8 which are respectively described as follows.

In operation 1, a substrate is provided, and an LT-GaN low-temperature epitaxy layer 102, an undoped GaN layer 103 and a first-type semiconductor layer 104 are sequentially grown on the substrate. In some exemplary implementations, the first-type semiconductor layer 104 has a thickness of 1-2.5 um, so that the micro light-emitting diode chip is thinned. In some exemplary implementations, the substrate is a sapphire substrate 101.

In operation 2, a groove is formed on the first-type semiconductor layer 104 by using a method of photolithography and etching processes. In some exemplary implementations, a trapezoidal groove is formed on the first-type semiconductor layer 101 by using a method of photolithography and etching processes.

In operation 3, the groove is isolated by using a photoresist 110 at the bottom of the groove of the first-type semiconductor layer 104, wherein the photoresist 110 is spaced from a sidewall of the groove. In some exemplary implementations, the photoresist 110 is provided in the middle of the groove, and a certain space is reserved between the photoresist 110 and the sidewall of the groove.

In operation 4, a reflective layer 107 having a high-reflectivity structure is grown on the first-type semiconductor layer 104. In some exemplary implementations, the reflective layer 107 is grown on a space other than the space occupied by the photoresist 110.

In operation 5, the photoresist 110 is removed.

It should be noted that photoresist (PR) is a method, required in a photolithography process, for defining the size of an element and manufacturing the positive and negative electrodes of the element. In the embodiment of the present disclosure, after the position of the photoresist (PR) on the element is defined, the subsequent reflective layer 107 is not completely evaporated on the first-type semiconductor layer 104, and is only evaporated on both sides of the first-type semiconductor layer 104, so that a light-emitting source of the element can pass through from the middle of the light-emitting layer 106 (MQW) (the non-evaporated reflective layer) to generate a torch light-field.

In operation 6, growing the first-type semiconductor layer 104 in the groove and on the reflective layer is continued, so as to wrap the reflective layer 107 in the first-type semiconductor layer 104.

In operation 7, a light-emitting layer 106 and a second-type semiconductor layer 105 are sequentially grown on the first-type semiconductor layer 104. In some exemplary implementations, the second-type semiconductor layer 105 has a thickness of 0.5-1.5 um, so that the MICRO-LED chip can reduce the light absorption effect.

In operation 8, a first electrode 108 is evaporated on the first-type semiconductor layer 104, and a second electrode 109 is evaporated on the second-type semiconductor layer 105.

In an exemplary implementation of the embodiment, the first-type semiconductor layer 104 is an N-type semiconductor layer, the second-type semiconductor layer is a P-type semiconductor layer, and the reflective layer 107 is grown on the N-type semiconductor layer.

In another exemplary implementation of the embodiment, the first electrode 108 is an N electrode, the second electrode 109 is a P electrode, the N electrode is evaporated on the N-type semiconductor layer, and the P electrode is evaporated on the P-type semiconductor layer.

In an exemplary implementation of the embodiment of the present disclosure, the first-type semiconductor layer 104 is a P-type semiconductor layer, the second-type semiconductor layer 105 is an N-type semiconductor layer, and the reflective layer 107 is grown on the P-type semiconductor layer. In addition, the first electrode 108 is a P electrode, the second electrode 109 is an N electrode, the P electrode is evaporated on the P-type semiconductor layer, and the N electrode is evaporated on the N-type semiconductor layer.

In an exemplary implementation of the embodiment, the reflective layer 107 is an oxide layer or an oxynitride layer. In addition, the reflective layer 107 is of a distributed Bragg reflector structure (DBR), wherein the DBR structure is a repetitive stack structure having two materials of different refractive indexes.

Referring to FIGS. 3 to 10, an embodiment of the present disclosure provides a display device. The display device comprises a display panel 200 and a plurality of micro light-emitting diode chips 100, and the plurality of micro light-emitting diode chips 100 are provided on the display panel 200 in an array and at intervals. Each of the plurality of micro light-emitting diode chips 100 comprises: a first-type semiconductor layer 104; a light-emitting layer 106 provided in the first-type semiconductor layer 104; a second-type semiconductor layer 105 provided in the light-emitting layer 106; and a reflective layer 107 provided on a light-exiting side of the light-emitting layer 106, so as to prevent divergence of the light emitted by the light-emitting layer 106. The details are as described above, and will not be described herein again.

In summary, the embodiments of the present disclosure provide a micro light-emitting diode chip and a manufacturing method therefor, and a display device. The micro light-emitting diode chip comprises a first-type semiconductor layer, a light-emitting layer and a second-type semiconductor layer which are sequentially stacked, wherein the light-emitting layer is located between the first-type semiconductor layer and the second-type semiconductor layer; and further comprises a reflective layer provided at a light-emitting side of the light-emitting layer, wherein the reflective layer is configured to block light emitted by the light-emitting layer to an edge of the micro light-emitting diode chip. In the embodiments of the present disclosure, the reflective layer having a high-reflectivity structure is provided on the first-type semiconductor layer, so that light emitted by the light-emitting layer to the edge of the micro light-emitting diode chip can be blocked, so as to reduce light divergence. As such, a distance between two adjacent micro light-emitting diode chips can be smaller, and a light cross phenomenon does not occur, thereby improving the resolution of a display.

It should be understood that the application of the present disclosure is not limited to the examples above. Those skilled in the art can make improvements or modifications according to the above descriptions, and all these improvements and modifications shall belong to the scope of protection of the appended claims of the present disclosure.

What is claimed is:

1. A micro light-emitting diode chip, comprising:
a first-type semiconductor layer, a light-emitting layer and a second-type semiconductor layer which are sequentially stacked, wherein the light-emitting layer is located between the first-type semiconductor layer and the second-type semiconductor layer; and
a reflective layer provided at a light-emitting side of the light-emitting layer, wherein the reflective layer is configured to block light emitted by the light-emitting layer to an edge of the micro light-emitting diode chip.

2. The micro light-emitting diode chip according to claim 1, wherein the reflective layer is embedded at an edge position of the first-type semiconductor layer.

3. The micro light-emitting diode chip according to claim 2, wherein the reflective layer is of a distributed Bragg reflector structure.

4. The micro light-emitting diode chip according to claim 1, wherein the first-type semiconductor layer is an N-type semiconductor layer, the second-type semiconductor layer is a P-type semiconductor layer, and the reflective layer is provided in the N-type semiconductor layer; or the first-type semiconductor layer is a P-type semiconductor layer, the second-type semiconductor layer is an N-type semiconductor layer, and the reflective layer is provided in the P-type semiconductor layer.

5. The micro light-emitting diode chip according to claim 2, wherein the micro light-emitting diode chip further comprises a substrate, the first-type semiconductor layer is provided on the substrate, and the reflective layer is located between the substrate and the light-emitting layer.

6. The micro light-emitting diode chip according to claim 5, wherein the micro light-emitting diode chip further comprises a low temperature-Gallium nitride (LT-GaN) low-temperature epitaxy layer and an undoped Gallium nitride (GaN) layer, wherein the LT-GaN low-temperature epitaxy layer is provided on the substrate, and the undoped GaN layer is provided on the LT-GaN low-temperature epitaxy layer.

7. A method for manufacturing a micro light-emitting diode chip, the method comprising:
growing a first-type semiconductor layer on a substrate;
forming a groove on the first-type semiconductor layer by using a method of photolithography and etching processes;
isolating the groove by using a photoresist at a bottom of the groove of the first-type semiconductor layer, wherein the photoresist is spaced from a sidewall of the groove;
growing, on the first-type semiconductor layer, a reflective layer having a high-reflectivity structure;
removing the photoresist;
continuing to grow the first-type semiconductor layer in the groove and on the reflective layer, so as to wrap the reflective layer in the first-type semiconductor layer; and
sequentially growing, on the first-type semiconductor layer, a light-emitting layer and a second-type semiconductor layer.

8. The method for manufacturing the micro light-emitting diode chip according to claim 7, wherein before growing the first-type semiconductor layer on the substrate, the method further comprises:
sequentially growing, on the substrate, a low temperature-Gallium nitride (LT-GaN) low-temperature epitaxy layer and an undoped Gallium nitride (GaN) layer; and
growing the first-type semiconductor layer on the substrate comprises:
growing the first-type semiconductor layer on the undoped GaN layer.

9. The method for manufacturing the micro light-emitting diode chip according to claim 8, wherein the reflective layer is of a distributed Bragg reflector structure.

10. A display device, comprising a display panel and a plurality of micro light-emitting diode chips, wherein the plurality of micro light-emitting diode chips are provided on the display panel in an array and at intervals, each of the plurality of micro light-emitting diode chips comprises:
a first-type semiconductor layer, a light-emitting layer and a second-type semiconductor layer which are sequentially stacked, wherein the light-emitting layer is located between the first-type semiconductor layer and the second-type semiconductor layer; and
a reflective layer provided at a light-emitting side of the light-emitting layer, wherein the reflective layer is configured to block light emitted by the light-emitting layer to an edge of the micro light-emitting diode chip.

11. The micro light-emitting diode chip according to claim 1, wherein the reflective layer is an oxide layer or an oxynitride layer.

12. The micro light-emitting diode chip according to claim 1, wherein the micro light-emitting diode chip further comprises an N electrode and a P electrode, wherein the N electrode is provided on the N-type semiconductor layer, and the P electrode is provided on the P-type semiconductor layer.

13. The method for manufacturing the micro light-emitting diode chip according to claim 7, wherein after sequentially growing, on the first-type semiconductor layer, the light-emitting layer and the second-type semiconductor layer, the method further comprises:
evaporating a first electrode on the first-type semiconductor layer, and evaporating a second electrode on the second-type semiconductor layer.

14. The method for manufacturing the micro light-emitting diode chip according to claim 7, wherein the first-type semiconductor layer is an N-type semiconductor layer, the second-type semiconductor layer is a P-type semiconductor layer, and the reflective layer is grown on the N-type semiconductor layer; the first electrode is an N electrode, the second electrode is a P electrode, the N electrode is evaporated on the N-type semiconductor layer, and the P electrode is evaporated on the P-type semiconductor layer.

15. The method for manufacturing the micro light-emitting diode chip according to claim 7, wherein the first-type semiconductor layer is a P-type semiconductor layer, the second-type semiconductor layer is an N-type semiconductor layer, and the reflective layer is grown on the P-type semiconductor layer; the first electrode is a P electrode, the second electrode is an N electrode, the P electrode is evaporated on the P-type semiconductor layer, and the N electrode is evaporated on the N-type semiconductor layer.

16. The method for manufacturing the micro light-emitting diode chip according to claim 7, wherein the reflective layer is an oxide layer or an oxynitride layer.

17. The display device according to claim 10, wherein the reflective layer is embedded at an edge position of the first-type semiconductor layer.

18. The display device according to claim 17, wherein the reflective layer is of a distributed Bragg reflector structure.

19. The display device according to claim 10, wherein the first-type semiconductor layer is an N-type semiconductor layer, the second-type semiconductor layer is a P-type semiconductor layer, and the reflective layer is provided in the N-type semiconductor layer; or the first-type semiconductor layer is a P-type semiconductor layer, the second-type semiconductor layer is an N-type semiconductor layer, and the reflective layer is provided in the P-type semiconductor layer.

20. The display device according to claim 17, wherein the micro light-emitting diode chip further comprises a substrate, the first-type semiconductor layer is provided on the substrate, and the reflective layer is located between the substrate and the light-emitting layer.
